(19) United States
(12) Patent Application Publication
(10) Pub. No.: US 2025/0275415 A1
(43) Pub. Date: Aug. 28, 2025

(54) Display Apparatus

(71) Applicant: LG Display Co., Ltd., Seoul (KR)

(72) Inventors: Hyeonggwang An, Incheon (KR); Myeongah Shin, Seoul (KR); JaeWon Shin, Paju-si (KR)

(21) Appl. No.: 19/025,578

(22) Filed: Jan. 16, 2025

(30) Foreign Application Priority Data
Feb. 27, 2024 (KR) 10-2024-0028012

(51) Int. Cl. H10K 59/80; H10K 102/00

(52) U.S. Cl. CPC H10K 59/87; H10K 2102/311; H10K 2102/351

(57) ABSTRACT

A display apparatus includes a display panel. The display apparatus further includes a backplate disposed below the display panel. The display apparatus further includes a plate assembly disposed below the backplate. The backplate and the plate assembly are coupled by a first bonding member, the display panel and the backplate are coupled by a second bonding member, and the first bonding member is formed to be thicker than the second bonding member.

### CROSS-REFERENCE TO RELATED APPLICATION

This application claims the priority of Republic of Korea Patent Application No. 10-2024-0028012 filed on Feb. 27, 2024, which is hereby incorporated by reference in its entirety.

### FIELD

The present specification relates to a display apparatus.

### BACKGROUND

Image display devices, which implement various information on screens, are key technologies in the information and communication era and include a cathode ray display panel, a liquid crystal display panel, an electrophoretic display panel, an organic light-emitting display panel, and the like.

In particular, organic light-emitting display panels and the like, which display images by controlling the amount of emission of light of organic light-emitting elements, are in the limelight to implement image display devices that are thinner and lighter in weight, are capable of being carried, and have high performance.

Because the organic light-emitting display panel is implemented as a spontaneous light-emitting display panel without a separate light source device, the organic light-emitting display panel may be manufactured to be light in weight and thin. In addition, the thin organic light-emitting display panel may be manufactured, which makes it easy to implement a foldable display device.

Meanwhile, the foldable display device has a plate assembly to protect a rear surface thereof and reinforce rigidity. The plate assembly is essential to implement foldability. However, an orange peel phenomenon may occur on an upper portion of a display device when rigid constituent elements, such as the plate assembly, are bonded to thin films. The orange peel phenomenon refers to the occurrence of a defect with an orange peel-like pattern on a surface of the display device. The orange peel phenomenon mainly refers to a phenomenon in which the surface of the display device, which needs to be flat, appears non-uniform because of fine unevenness, and the orange peel phenomenon may adversely affect the quality. The orange peel phenomenon is often observed on outer layers, such as a cover window, a plastic cover, and a protective film, of the display device.

### SUMMARY

An object to be achieved by the present disclosure is to provide a display apparatus in which a plate assembly is provided on a rear surface of the display apparatus, and no orange peel phenomenon occurs on a front surface.

Objects of the present disclosure are not limited to the above-mentioned objects, and other objects, which are not mentioned above, can be clearly understood by those skilled in the art from the following descriptions.

In order to achieve the above-mentioned object, an embodiment of the present disclosure provides a display apparatus including: a display panel; a backplate disposed below the display panel; and a plate assembly disposed below the backplate, in which the backplate and the plate assembly are coupled by a first bonding member, the display panel and the backplate are coupled by a second bonding member, and the first bonding member is formed to be thicker than the second bonding member.

Other detailed matters of the exemplary embodiments are included in the detailed description and the drawings.

The present disclosure may reduce the orange peel phenomenon on the foldable display apparatus.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded view of a display apparatus according to an embodiment of the present disclosure;

FIG. 2 is a cross-sectional view of the display apparatus according to the embodiment of the present disclosure;

FIG. 3 is a view for explaining an orange peel phenomenon;

FIG. 4 is a partially cross-sectional view of the display apparatus according to the embodiment of the present disclosure; and

FIG. 5 is a partially cross-sectional view of the display apparatus according to the embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure.

The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is referred to as being “on” another element or layer, it may be directly on the other element or layer, or intervening elements or layers may be present therebetween. When a component is “linked”, “coupled”, or “connected” to another component, the component may be directly linked or connected to the other component. However, unless specifically stated otherwise, it should be understood that a third component may be interposed between the components which may be indirectly linked or connected.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawings are illustrated for convenience of explanation and are not limited to the size and the thickness of the component illustrated in embodiments of the present disclosure.

The features of various embodiments of the present disclosure can be partially or entirely coupled to or combined with each other and can be interlocked and operated in technically various ways, and respective embodiments can be carried out independently of or in association with each other.

In the present specification, unless otherwise specifically stated, a modulus refers to a Young's modulus value measured at room temperature (25° C.) by a tensile tester.

Hereinafter, various embodiments of the present disclosure will be described in detail with reference to the accompanying drawings.

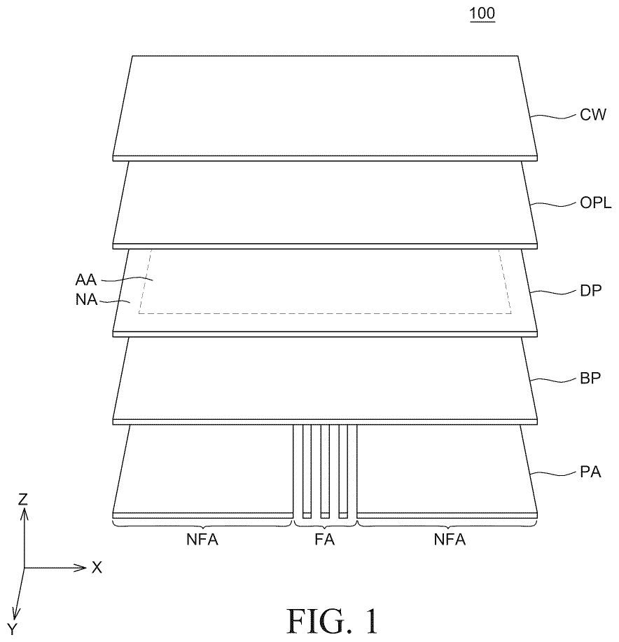

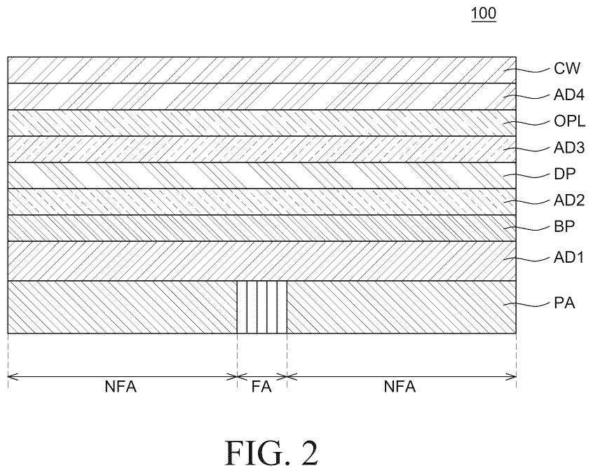

FIG. 1 is an exploded view of a display apparatus according to an embodiment of the present disclosure. FIG. 2 is a cross-sectional view of the display apparatus according to the embodiment of the present disclosure.

With reference to FIGS. 1 and 2, a display panel DP refers to a panel for implementing images. Organic light-emitting element for implementing images, and circuits, lines, and components for operating the organic light-emitting elements may be disposed on the display panel DP.

The display panel DP includes a display area AA, a non-display area NA, a folding area FA, and non-folding areas NFA.

The display area AA is an area for displaying images and a plurality of pixels including organic light-emitting elements are arrayed in the display area AA. The organic light-emitting element for displaying images may be disposed in the display area AA, and a circuit part for operating the organic light-emitting element may be disposed in the display area AA. In the present disclosure, for convenience of description, it is assumed that the display apparatus is a display apparatus 100 including the display panel DP having the organic light-emitting element. However, the present disclosure is not limited thereto.

The circuit part may include various thin-film transistors, capacitors, lines, and the like for operating the organic light-emitting elements. For example, the circuit part may include various components such as a thin-film driving transistor, a switching thin-film transistor, a storage capacitor, a gate line, and a data line. However, the present disclosure is not limited thereto.

The non-display area NA is an area in which no image is displayed. Circuits, lines, components, and the like for operating the organic light-emitting elements in the display area AA are disposed in the non-display area NA. Various drive ICs, such as a gate driver IC and a data driver IC, and various drive circuits may be disposed in the non-display area NA. For example, various ICs and various drive circuits may be mounted in the non-display area NA of the display panel DP in a gate-in-panel (GIP) manner or connected to the display panel DP in a tape-carrier-package (TCP) or chip-on-film (COF) manner.

Meanwhile, the display panel DP may also be defined as the display area AA and the non-display area NA or defined as the folding area FA and non-the folding area NFA.

The folding area (or folding portion or foldable area) FA is an area in which the display panel DP is folded when the display apparatus 100 is folded. The folding area FA may include a part of the display area AA and a part of the non-display area NA. In the present disclosure, an example is described in which the folding area FA includes a part of the display area AA and a part of the non-display area NA. However, the present disclosure is not limited thereto. The non-display area NA may be present only in a partial area outside the display area AA. Therefore, the folding area FA may include only a part of the display area AA.

The folding area FA may be folded along a particular radius of curvature about a folding axis. Specifically, the folding axis may be a Y-axis. In case that the folding area FA is folded about the folding axis, the folding area FA may define a part of a curved line, a part of a circle, or a part of an ellipse. A radius of curvature of the folding area FA refers to a radius of a curved line, circle, or ellipse corresponding to a part of the curved line, circle, or ellipse defined by the folding area FA. In the present disclosure, an example is described in which the folding axis is positioned in the Y-axis direction in the folding area FA, the non-folding area NFA extends in an X-axis direction from the folding area FA and is perpendicular to the folding axis. However, the present disclosure is not limited thereto.

The non-folding area (or non-folding portion or non-foldable area) NFA is an area in which the display panel DP is not folded when the display apparatus 100 is folded. That is, the non-folding area NFA is an area in which the display panel DP is kept in a flat state when the display apparatus 100 is folded. The non-folding area NFA may include a part of the display area AA and a part of the non-display area NA.

The non-folding areas NFA may be areas positioned at two opposite sides of the folding area FA. That is, the non-folding area NFA may be an area extending in the Y-axis direction based on the folding axis. In this case, the folding area FA may be defined between the non-folding areas NFA. Therefore, when the display panel DP is folded about the folding axis, the non-folding areas NFA may face each other.

As illustrated in FIG. 1, the display apparatus 100 may include a cover window CW, an optical layer OPL, the display panel DP, a backplate BP, and/or a plate assembly PA. As illustrated in FIG. 2, the display apparatus 100 may further include a first bonding member, a second bonding member, and/or a third bonding member.

The display panel (or an image display member) DP includes a substrate. Because the substrate included in the display panel DP may be made of a plastic material having flexibility, the substrate is a foldable flexible substrate. In this case, for example, a process of manufacturing the display apparatus 100 is performed in a situation in which a panel manufacturing substrate made of glass is disposed on a lower portion of the substrate, members such as a polarizing plate may be disposed on the display panel DP, and then the panel manufacturing substrate may be released.

The backplate BP is positioned on a lower portion of the display panel DP. The backplate BP may be uniformly disposed in an entire area of the lower portion of the display panel DP. In this case, the backplate BP is a substrate having rigidity to support the display panel DP and having flexibility to ensure foldability. In this case, for example, the backplate BP may be made of a polymer material with excellent flexibility, such as polyamide, polyurethane, polymethyl methacrylate, polycarbonate, polyvinyl alcohol, acrylonitrile-butadiene-styrene, polyethylene terephthalate, silicone, polyimide, or polyamide-imide. A modulus of the backplate may be 1 MPa to 40 MPa. A thickness of the backplate may be 100 μm to 250 μm. However, the present disclosure is not limited thereto.

A second bonding member AD2 is positioned between the display panel DP and the backplate BP. The second bonding member AD2 may be uniformly disposed in an entire area of a top surface of the backplate BP and attach the display panel DP and the backplate BP. In this case, for example, the second bonding member AD2 may be made of a transparent bonding member such as optical clear resin (OCR) or optical clear adhesive (OCA). However, the present disclosure is not limited thereto.

The plate assembly PA may be positioned below the backplate BP. The plate assembly PA may be made of a material having rigidity and positioned below the display panel DP. The plate assembly PA serves to support the display panel DP and support and maintain the shape of the display apparatus 100 having the display panel DP. The plate assembly PA may include a plate top and a plate bottom. For example, the plate bottom may be made of a metallic material such as stainless steel or Invar or a plastic material such as polymethyl methacrylate, polycarbonate, polyvinyl alcohol, acrylonitrile-butadiene-styrene, polyethylene terephthalate, silicone, or polyurethane. The plate top may be disposed between the backplate BP and the plate bottom and made of a material with high rigidity to reinforce rigidity of the panel. The plate top may be made of a metallic material such as stainless steel, Invar, aluminum series, or magnesium. As another example, the plate top may be made of a plastic material such as polymethyl methacrylate, polycarbonate, or polyurethane. The plate top and the plate bottom may be integrally formed, and the plate top or plate bottom may be omitted when necessary.

The plate assembly PA have an opening pattern corresponding to the folding area FA of the display panel DP. The opening pattern may refer to a structure in which blocking portions (or blocking areas) and opening portions (or opening areas) continuously and alternately disposed. Therefore, the opening pattern of the plate assembly PA may allow the plate assembly PA to be folded at a portion corresponding to the folding area FA of the display panel DP. The plate assembly PA may have a thickness of 0.18 mm or more and 0.22 mm or less. However, the present disclosure is not limited thereto.

A first bonding member AD1 may be positioned between the backplate BP and the plate assembly PA. The first bonding member AD1 may be uniformly disposed in an entire area of a bottom surface of the backplate BP and attach the backplate BP and the plate assembly PA. The first bonding member AD1 may be made of the same material as the second bonding member AD2. However, the present disclosure is not limited thereto.

The optical layer OPL may be disposed on the display panel DP. The optical layer OPL may uniformly transmit light emitted from the display panel DP to the outside without reducing the luminance of the flexible display apparatus 100 and absorb or reflect external light to improve display quality. For example, the optical layer OPL may be a polarizing plate. However, the present disclosure is not limited thereto.

The display panel DP and the optical layer OPL may be bonded by a third bonding member AD3. The third bonding member AD3 may include optically clear adhesive (OCA) or pressure sensitive adhesive (PSA). However, the present disclosure is not limited thereto.

The cover window CW is disposed on the optical layer OPL. The cover window CW is disposed adjacent to a display surface on which images are displayed. The cover window CW protects the display panel DP so that the display panel DP is not damaged or scratched by an external impact. The cover window CW may be made of a thin glass or film. The cover window CW may include a transparent substrate made of polyimide, polyamide-imide, or the like. The cover window CW may include one or more functional layers selected from a hard coating layer, which includes acrylic-based resin, epoxy-based resin, or silicon-based resin, an anti-fingerprint layer, an antifouling layer, an anti-reflection layer, an anti-glare layer, and a protective layer. However, the present disclosure is not limited thereto.

The cover window CW and the optical layer OPL may be bonded by a fourth bonding member AD4. The fourth bonding member AD4 may include optically clear adhesive (OCA) or pressure sensitive adhesive (PSA). However, the present disclosure is not limited thereto.

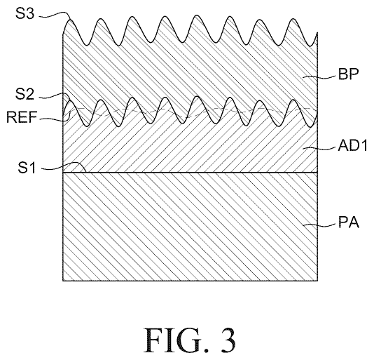

FIG. 3 is a view for explaining an orange peel phenomenon.

In the case of the foldable display apparatus, a problem of an orange peel phenomenon may be caused by the bonding member. More specifically, when the thin layer and the bonding member are stacked, the layers, which are attached to each other, are freely deformed to implement an equilibrium of forces, and the orange peel phenomenon slightly occurs during the process in which the equilibrium of forces is implemented. However, when the bonding member is stacked on a rigid member such as the plate assembly PA, a restrictive force, which hinders natural deformation of a surface attached to the rigid member, is generated. The restrictive force may worsen the orange peel phenomenon.

With reference to FIG. 3, the first bonding member AD1 may be stacked on an upper portion of the plate assembly PA. Because the plate assembly PA is a rigid member, an original surface shape of a first surface S1 is maintained. In other words, the original shape of the first surface S1 may be maintained regardless of a stack of the first bonding member AD1. In contrast, the first bonding member AD1 may include a deformation pattern provided on a second surface S2 opposite to the first surface S1. The second surface S2 is a top surface of the first bonding member AD1, and the first surface S1 is a bottom surface of the first bonding member AD1.

With reference to FIG. 3, the deformation pattern formed on the second surface S2 may cause upward deformation. For example, a deformation pattern may be formed on a third surface S3 by the deformation pattern formed on the second surface S2. The deformation pattern formed on the second surface S2 may transfer the deformation to the third surface S3. The deformation pattern formed on the bottom surface (e.g., the first surface S1, the second surface S2, or the like) may transfer the deformation pattern to the top surface. As a result, the deformation pattern may be transferred to an upper portion of the display apparatus, and the transfer of the deformation may be found as the orange peel phenomenon. In case that the restrictive force, which is transmitted as described above, is low, the orange peel phenomenon may be reduced, as indicated by a reference line REF.

The present disclosure proposes a new design that reduces a degree of deformation of the deformation pattern transferred to the top surface of the bonding member when the bonding member (e.g., the first bonding member AD1) is stacked on a rigid material such as the plate assembly PA. Hereinafter, the display apparatus according to various embodiments of the present disclosure will be described.

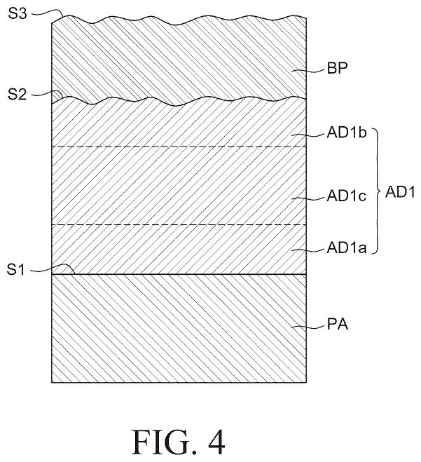

FIG. 4 is a partially cross-sectional view of the display apparatus according to the embodiment of the present disclosure.

With reference to FIG. 4, the display apparatus according to the embodiment may include the plate assembly PA, the first bonding member AD1, and/or the backplate BP. The display apparatus according to the embodiment may further include the display panel DP and the cover window CW disposed above the backplate BP. In addition, the display apparatus according to the embodiment may further include the optical layer OPL disposed between the display panel DP and the cover window CW. The descriptions of the plate assembly PA, the backplate BP, the display panel DP, the optical layer OPL, and the cover window CW in FIG. 4 are redundant with the descriptions of those of the display apparatus described with reference to FIGS. 1 and 2. For convenience of description, the repeated descriptions will be omitted, and differences will be described.

With reference back to FIG. 4, the display apparatus according to the embodiment includes the plate assembly PA, and the backplate BP stacked on the plate assembly PA. The plate assembly PA and the backplate BP may be bonded by the first bonding member AD1.

The first bonding member AD1 may include the first surface S1 and the second surface S2, the first surface S1 may be the bottom surface of the first bonding member AD1, and the second surface S2 may be the top surface of the first bonding member AD1. The first surface S1 of the first bonding member AD1 is in contact with the plate assembly PA. The second surface S2 of the first bonding member AD1 is in contact with the backplate BP. In the present specification, the first surface S1 may be referred to as a top surface of the plate assembly PA. In addition, in the present specification, the second surface S2 may be referred to as a bottom surface of the backplate BP, which is not restrictive.

According to the embodiment of the present disclosure, the first bonding member AD1 may include a plurality of portions. For example, the first bonding member AD1 may include a first portion AD1a provided to be in contact with the plate assembly PA, a second portion AD1b provided to be in contact with the backplate BP, and a third portion AD1c positioned between the first portion AD1a and the second portion AD1b. The first portion AD1a, the second portion AD1b, and the third portion AD1c may be integrated. The first portion AD1a, the second portion AD1b, and the third portion AD1c may be made of substantially the same material.

A degree of deformation of the second surface S2 may be reduced by introducing the third portion AD1c between the first portion AD1a and the second portion AD1b. In detail, because the third portion AD1c is introduced, an overall thickness of the first bonding member AD1 may be increased, and the restrictive force transmitted from the first surface S1 may be decreased. The restrictive force, which is transmitted from the first surface S1, may be reduced by the third portion AD1c, such that a degree of deformation of the second surface S2 may be reduced. In other words, at the middle portion of the first bonding member AD1, the restrictive force transmitted from the first surface S1 may be reduced, and the degree of deformation of the second surface S2 may be reduced. As described above, the thickness of the first bonding member AD1 may be increased by introducing the third portion AD1c, such that the present disclosure may reduce the orange peel phenomenon of the display apparatus.

Because the third portion AD1c is introduced, the thickness of the first bonding member AD1 may be larger than the thickness of each of the remaining bonding members. For example, the thickness of the first bonding member AD1 may be larger than a thickness of the second bonding member AD2. The thickness of the first bonding member AD1 may be 50 μm or more, e.g., 50 μm to 100 μm. When the thickness of the first bonding member AD1 is 50 μm or more, a degree of the orange peel phenomenon may be improved by about 13%.

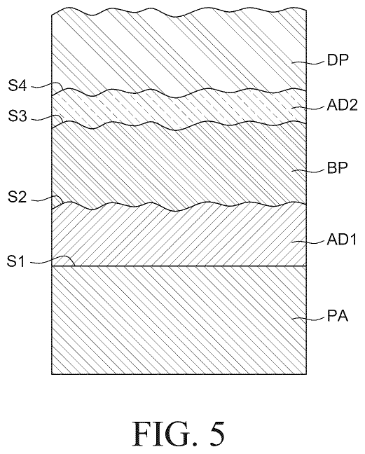

FIG. 5 is a partially cross-sectional view of the display apparatus according to the embodiment of the present disclosure.

With reference to FIG. 5, the display apparatus according to the embodiment may include the plate assembly PA, the first bonding member AD1, the backplate BP, the second bonding member AD2, and/or the display panel DP. The display apparatus according to the embodiment may further include the cover window CW. The display apparatus according to the embodiment may further include the optical layer OPL disposed between the display panel DP and the cover window CW. The descriptions of the plate assembly PA, the backplate BP, the display panel DP, the optical layer OPL, and the cover window CW in FIG. 5 are redundant with the descriptions of those of the display apparatus described with reference to FIGS. 1 and 2. For convenience of description, the repeated descriptions will be omitted, and differences will be described.

With reference back to FIG. 5, the display apparatus according to the embodiment includes the plate assembly PA, and the backplate BP stacked on the plate assembly PA. The plate assembly PA and the backplate BP may be bonded by the first bonding member AD1.

The first bonding member AD1 may include the first surface S1 and the second surface S2, the first surface S1 may be the bottom surface of the first bonding member AD1, and the second surface S2 may be the top surface of the first bonding member AD1. The first surface S1 of the first bonding member AD1 is in contact with the plate assembly PA. The second surface S2 of the first bonding member AD1 is in contact with the backplate BP. In the present specification, the first surface S1 may be referred to as a top surface of the plate assembly PA. In addition, in the present specification, the second surface S2 may be referred to as a bottom surface of the backplate BP, which is not restrictive.

The display apparatus may further include the display panel DP disposed on the backplate BP. The display panel DP and the backplate BP may be bonded by the second bonding member AD2.

The second bonding member AD2 may include the third surface S3 and a fourth surface S4, the third surface S3 may be the bottom surface of the second bonding member AD2, and the fourth surface S4 may be the top surface of the second bonding member AD2. The third surface S3 of the second bonding member AD2 is in contact with the backplate BP. The fourth surface S4 of the second bonding member AD2 is in contact with the display panel DP. In the present specification, the third surface S3 may be referred to as a top surface of the backplate. In addition, in the present specification, the fourth surface S4 may be referred to as a bottom surface of the display panel DP, which is not restrictive.

According to the embodiment of the present disclosure, the second bonding member AD2 may have a high modulus and/or a small thickness. For example, the second bonding member AD2 may have a higher modulus than the first bonding member AD1. For example, the second bonding member AD2 may have a smaller thickness than the first bonding member AD1. For example, the second bonding member AD2 may have a modulus about 5 times or more higher than a modulus of the first bonding member AD1. The second bonding member AD2 may have a thickness of 15 μm or less, particularly 13 μm to 15 μm. The second bonding member AD2 having the modulus and/or the thickness improves a degree of the orange peel phenomenon by about 20%.

According to the embodiment of the present disclosure, the first bonding member AD1 according to the embodiment illustrated in FIG. 5 may be substantially identical to the first bonding member AD1 described above with reference to FIG. 4. In other words, because the third portion AD1c is introduced, the first bonding member AD1 may be configured to be thicker than the other bonding members. The first bonding member AD1 may have a thickness of 50 μm or more, e.g., 50 μm to 100 μm. When the first bonding member AD1 has a thickness of 50 μm or more and the second bonding member AD2 is configured to have a thickness of 15 μm or less and a high modulus, a degree of the orange peel phenomenon is improved by about 34% in comparison with the related art.

The exemplary embodiments of the present disclosure can also be described as follows:

According to an aspect of the present disclosure, there is provided a display apparatus. The display apparatus includes a display panel. The display apparatus further includes a backplate disposed below the display panel. The display apparatus further includes a plate assembly disposed below the backplate. The backplate and the plate assembly are coupled by a first bonding member, the display panel and the backplate are coupled by a second bonding member, and the first bonding member is formed to be thicker than the second bonding member.

A thickness of the first bonding member may be 50 μm or more and 100 μm or less.

A thickness of the second bonding member may be 15 μm or less.

The second bonding member may have a higher modulus than the first bonding member.

The first bonding member may be divided into a first portion, a second portion, and a third portion, the first portion is in contact with the plate assembly, the second portion is in contact with the backplate, and the third portion is disposed between the first portion and the second portion.

The first portion, the second portion, and the third portion may be made of the same material.

The first bonding member may comprise a first surface and a second surface. The first surface may be in contact with the plate assembly. The second surface may be in contact with the backplate. The first bonding member may be in contact with the plate assembly so that a restrictive force is transmitted from the first surface to the second surface of the first bonding member. The third portion may reduce the transmitted restrictive force.

The display panel may comprise an organic light-emitting element.

The plate assembly may include a rigid material.

The display apparatus may further comprise: an optical layer disposed above the display panel; and a cover window disposed above the optical layer. The cover window may include a film.

A standard deviation (slope stdev) of a slope of surface roughness of the cover window may be 0.27 μm/mm or less or 0.22 μm/mm or more and 0.27 μm/mm or less.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the appended claims, and all the technical concepts in the equivalent scope thereof should be construed as falling within the scope of the present disclosure.

What is claimed is:

1. A display apparatus comprising:
a display panel;
a backplate below the display panel; and
a plate assembly below the backplate,
wherein the backplate and the plate assembly are coupled by a first bonding member, the display panel and the backplate are coupled by a second bonding member, and the first bonding member is thicker than the second bonding member.

2. The display apparatus of claim 1, wherein a thickness of the first bonding member is 50 μm or more and 100 μm or less.

3. The display apparatus of claim 2, wherein a thickness of the second bonding member is 15 μm or less.

4. The display apparatus of claim 1, wherein the second bonding member has a modulus that is higher than a modulus of the first bonding member.

5. The display apparatus of claim 1, wherein the first bonding member is divided into a first portion, a second portion, and a third portion, the first portion is in contact with the plate assembly, the second portion is in contact with the backplate, and the third portion is between the first portion and the second portion.

6. The display apparatus of claim 5, wherein the first portion, the second portion, and the third portion include a same material.

7. The display apparatus of claim 6, wherein the first bonding member comprises a first surface and a second surface,
wherein the first surface is in contact with the plate assembly,
wherein the second surface is in contact with the backplate,
wherein the first bonding member is in contact with the plate assembly so that a restrictive force is transmitted from the first surface to the second surface of the first bonding member, and
wherein the third portion reduces the transmitted restrictive force.

8. The display apparatus of claim 1, wherein the display panel comprises an organic light-emitting element.

9. The display apparatus of claim 1, wherein the plate assembly includes a rigid material.

10. The display apparatus of claim 1, further comprising:
an optical layer above the display panel; and
a cover window above the optical layer,
wherein the cover window includes a film.

11. The display apparatus of claim 10, wherein a standard deviation of a slope of surface roughness of the cover window is 0.27 μm/mm or less or 0.22 μm/mm or more and 0.27 μm/mm or less.

12. A display apparatus comprising:
a display panel;
a backplate below the display panel; and
a plate assembly below the backplate,
wherein the backplate and the plate assembly are coupled by a first bonding member, the display panel and the backplate are coupled by a second bonding member, and
the first bonding member and the second bonding member are set to satisfy one or more of a following conditions: the first bonding member is thicker than the second bonding member and the first bonding member has a modulus that is lower than a modulus of the second bonding member.

13. The display apparatus of claim 12, wherein the modulus of the second bonding member is modulus 5 times or more higher than the modulus of the first bonding member.

14. The display apparatus of claim 12, wherein a thickness of the first bonding member is 50 μm or more and 100 μm or less.

15. The display apparatus of claim 14, wherein a thickness of the second bonding member is 15 μm or less.
